(19) United States
(12) Patent Application Publication
(10) Pub. No.: US 2026/0342053 A1
(43) Pub. Date: Oct. 29, 2026

(54) POWER SUPPLY SYSTEM AND POWER SHELF AND RACK THEREOF

(71) Applicant: Delta Electronics, Inc., Taoyuan City (TW)

(72) Inventors: Chi-Yuan Tseng, Taoyuan City (TW); Chi-Shou Ho, Taoyuan City (TW); Ching-Tang Chang, Taoyuan City (TW)

(21) Appl. No.: 19/461,545

(22) Filed: Jan. 27, 2026

Related U.S. Application Data
(60) Provisional application No. 63/793,092, filed on Apr. 23, 2025.

(30) Foreign Application Priority Data
Dec. 4, 2025 (CN) 202511813582.X

(51) Int. Cl. H02B 1/21; H05K 7/14; H05K 7/18; G06F 1/18; H02B 1/36

(52) U.S. Cl. CPC H02B 1/21; H05K 7/1492; H05K 7/18; G06F 1/189; H02B 1/36

(57) ABSTRACT

The present disclosure provides a power supply system, and a power shelf and a rack thereof. The power shelf is connected to the rack through a plurality of connectors. Each connector includes two connection terminals respectively connected to a first input busbar and/or a second input busbar. The plurality of connectors include a first connector and two second connectors, and the two second connectors are respectively arranged on two opposite sides of the first connector. The first connector is configured to connect to a first plug-in interface of the rack busbar along a docking direction, and the two second connectors are configured to connect to a second plug-in interface and a third plug-in interface of the rack busbar along the docking direction perpendicular to the vertical direction. Multiple connections are used between the power shelf and the rack. It allows the power supply system to provide high output current.

### CROSS-REFERENCE TO RELATED APPLICATION

This application claims the benefit of U.S. Provisional Application No. 63/793,092 filed on Apr. 23, 2025, and entitled “POWER SHELF WITH ENHANCED OUTPUT CURRENT CAPABILITY”. This application claims priority to China Patent Application No. 202511813582.X filed on Dec. 04, 2025. The entireties of the above-mentioned patent applications are incorporated herein by reference for all purposes.

### FIELD OF THE INVENTION

The present disclosure relates to a power supply system structure, and more particularly to a power supply system and a power shelf and a rack thereof.

### BACKGROUND OF THE INVENTION

A power shelf is a modular system for centrally managing and distributing the power. It is a power supply system widely used in the data centers, the servers and other suitable infrastructures.

In a conventional power supply system, the power shelf is connected to the rack busbar of the rack via one single clip-on connector, so as to provide power to loads in the same rack or different racks. However, when the clip-on connector serves as the output terminal of the power shelf, a maximum current withstand of the clip-on connector is limited, so that the power shelf cannot be used for high-power output applications. On the other hand, due to the limitations of compatibility with other devices, the specifications of the rack cannot be significantly changed. It results in the current structure of rack busbar structure and the single clip connector being unable to provide sufficient output current.

In view of this, there is a need of providing a power supply system and a power shelf and a rack thereof, allowing the power supply system to provide high output current and addressing the deficiencies of the prior arts.

### SUMMARY OF THE INVENTION

An object of the present disclosure is to provide a power supply system and a power shelf and a rack thereof, allowing the power supply system to provide sufficient output current.

In accordance with an aspect of the present disclosure, a power supply system is provided and comprises a rack and at least one power shelf. The rack comprises a rack body and a rack busbar. The rack body comprises a plurality of accommodation seats stacked in a vertical direction. The rack busbar is arranged in the vertical direction and disposed adjacent to the plurality of accommodation seats, and the rack busbar comprises a main body and two branch elements. The main body is extended in the vertical direction and forms a first plug-in interface. The two branch elements are disposed on two opposite sides of the main body, and respectively forms a second plug-in interface and a third plug-in interface. The at least one power shelf is detachably received in one of the plurality of accommodation seats. The at least one power shelf comprises a housing, a first input busbar, a second input busbar and a plurality of connectors. The housing comprises a rack connection edge, an accommodation space and an installation space for receiving one or more power supply units and/or load units. The first input busbar and the second input busbar are disposed in the accommodation space for connecting the one or more power supply units and/or load units. The plurality of connectors are disposed at the rack connection edge of the housing and spaced apart along a direction parallel to the rack connection edge, wherein each of the plurality of connectors comprises two connection terminals, which are connected to the first input busbar and/or the second input busbar, wherein the plurality of connectors comprise a first connector and two second connectors, the two second connectors are respectively arranged on two opposite sides of the first connector, the first connector is configured to connect to the first plug-in interface of the rack busbar along a docking direction, the two second connectors are configured to connect to the second plug-in interface and the third plug-in interface of the rack busbar along the docking direction, and the vertical direction and the docking direction are perpendicular to each other.

In accordance with another aspect of the present disclosure, a power shelf is provided and comprises a housing, a first input busbar, a second input busbar and a plurality of connectors. The housing comprises a rack connection edge, an accommodation space and an installation space for receiving one or more power supply units and/or load units. The first input busbar and the second input busbar are disposed within the accommodation space for connecting the one or more power supply units and/or load units. The plurality of connectors are disposed at the rack connection edge of the housing and spaced apart along a direction parallel to the rack connection edge, wherein each of the plurality of connectors comprises two connection terminals, which are respectively connected to the first input busbar and/or the second input busbar, wherein the plurality of connectors comprise a first connector and two second connectors, the two second connectors are respectively arranged on two opposite sides of the first connector, the first connector is configured to connect to a main body of a rack busbar along a docking direction, and the two second connectors are configured to connect to two branch elements of the rack busbar along the docking direction, wherein the main body is extended in a vertical direction, the two branch elements are respectively arranged on two opposite sides of the main body, and the vertical direction and the docking direction are perpendicular to each other.

In accordance with a further aspect of the present disclosure, a rack is provided and comprises a rack body and a rack busbar. The rack body comprises a plurality of accommodation seats stacked in a vertical direction. The rack busbar is arranged in the vertical direction and disposed adjacent to the plurality of accommodation seats, wherein the rack busbar comprises a main body and two branch elements. The main body is extended in the vertical direction and forms a first plug-in interface, wherein the first plug-in interface is configured to connect to a first connector of a power shelf along a docking direction, and the vertical direction is perpendicular to the docking direction. The two branch elements are disposed on two opposite sides of the main body, and respectively forms a second plug-in interface and a third plug-in interface, wherein the second plug-in interface and the third plug-in interface are configured to connect to two second connectors of the power shelf along the docking direction, and the two second connectors are disposed on two opposite sides of the first connector.

### BRIEF DESCRIPTION OF THE DRAWINGS

The above contents of the present disclosure will become more readily apparent to those ordinarily skilled in the art after reviewing the following detailed description and accompanying drawings, in which:

FIGS. 1 and 2 are structural perspective views illustrating an embodiment of a power supply system of the present disclosure;

FIG. 3 is a schematic structural view illustrating a power shelf corresponding to a rack busbar according to a first embodiment of the present disclosure;

FIG. 4 is a partial exploded view of FIG. 3;

FIG. 5 is a top view illustrating partial components in FIG. 3;

FIG. 6 is a top view illustrating partial components of a power shelf and a rack busbar according to a second embodiment of the present disclosure;

FIG. 7 is a top view illustrating partial components of a power shelf and a rack busbar according to a third embodiment of the present disclosure; and

FIG. 8 is a top view illustrating partial components of a power shelf and a rack busbar according to a fourth embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may comprise embodiments in which the first and second features are formed in direct contact, and may also comprise embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “front,” “rear,” “upper,” “lower,” “left,” “right,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the "first," "second" and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, "and/or" and the like may be used herein for including any or all combinations of one or more of the associated listed items.

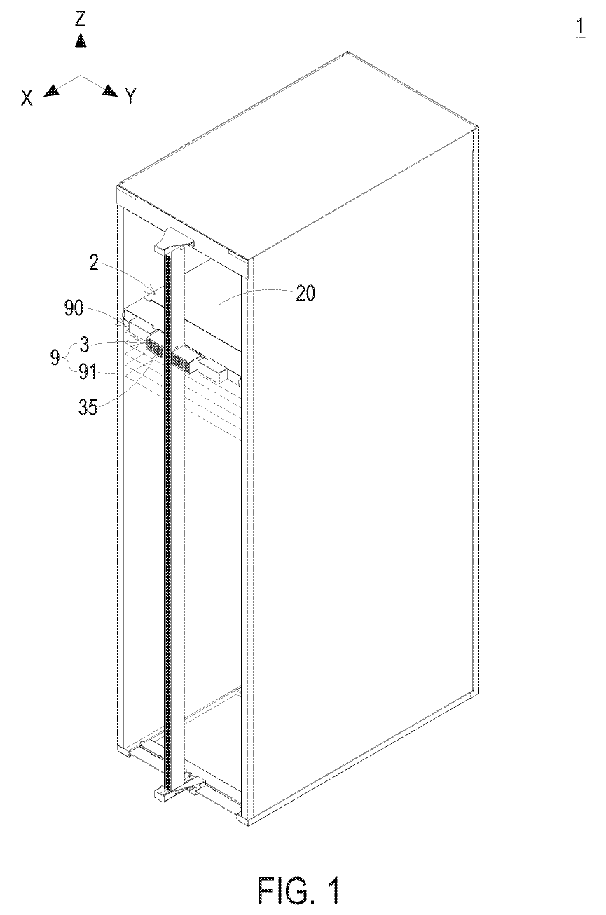

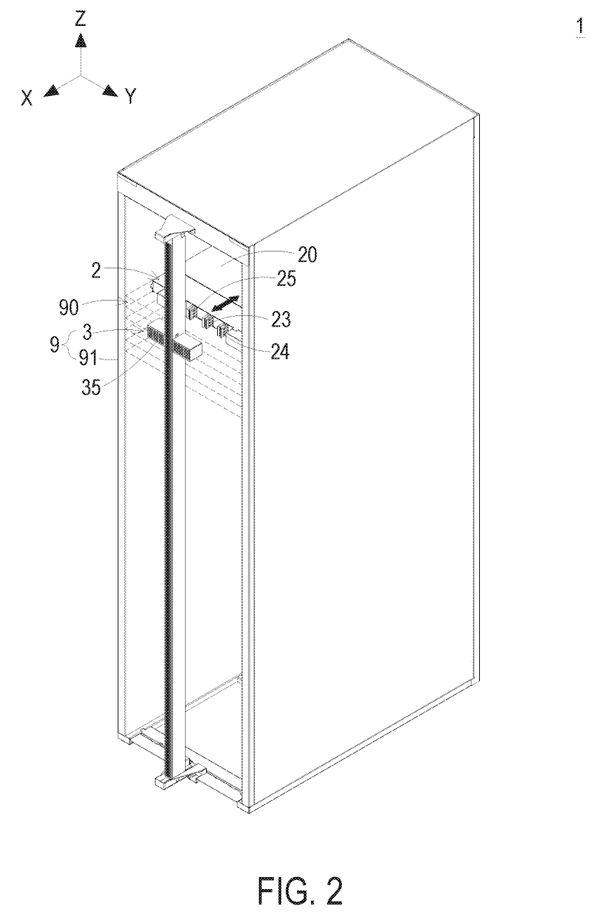

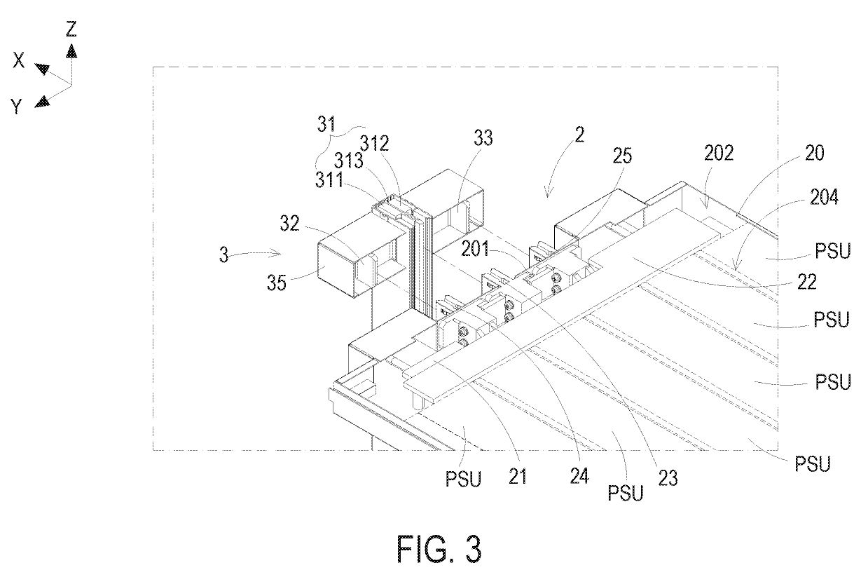

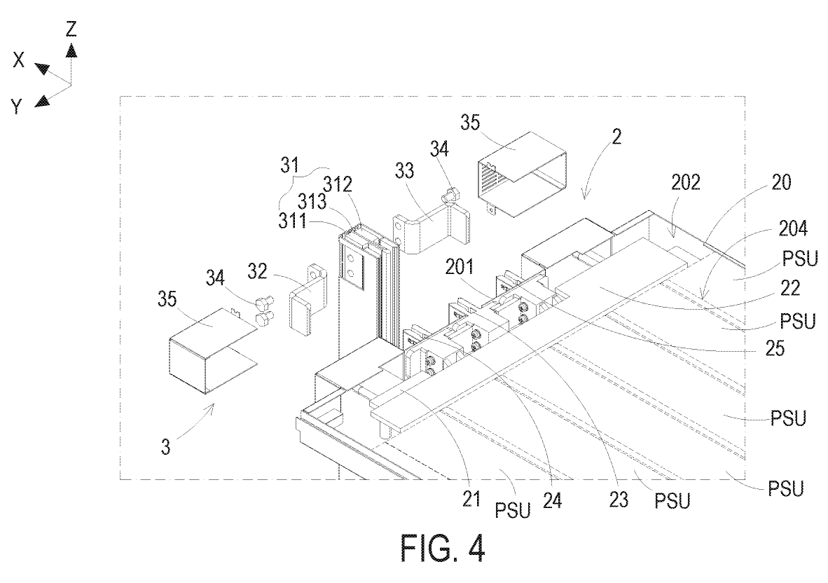

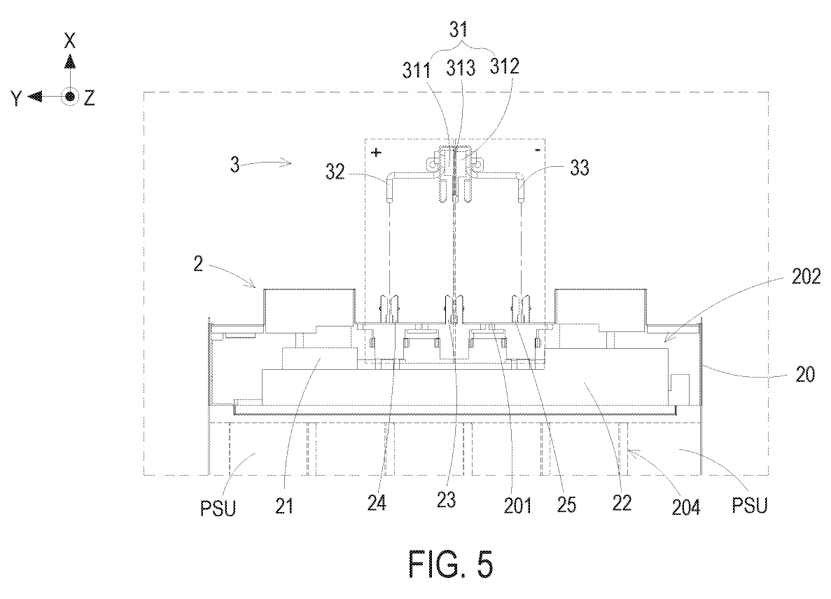

FIGS. 1 - 5 show an embodiment of a power supply system of the present disclosure. The power supply system 1 comprises a rack 9 and at least one power shelf 2. The rack 9 comprises a rack body 91 and a rack busbar 3. The rack body 91 comprises a plurality of accommodation seats 90. Preferably but not exclusively, the accommodation seats 90 are arranged with the same size or different sizes, and stacked along a vertical direction of the rack body 91 (i.e., the Z axial direction in the drawing). For example, the accommodation seats 90 are arranged to the height of 1 to N rack units (RU) or open units (OCP, OpenU, OU), which will be referred to as 1U, 2U... NU (N is a positive integer). In the embodiment, the power shelf 2 is 1U in height and detachably accommodated within any one of the 1U accommodation seats 90. Moreover, the power shelf 2 is docked with the rack busbar 3 along a docking direction (i.e., the X axial direction). For ease of explanation, the present disclosure only describes one single accommodation seat 90 corresponding to a 1U power shelf 2, but it is not intended to limit the scope of the present disclosure. For example, the rack 9 is used to receive one or more 1U or NU power shelves, backup battery unit (BBU) shelves, server shelves, power distribution unit shelves, one or more other power supply shelves and/or other load shelves. In the embodiment, the rack busbar 3 is arranged adjacent to the rear edge of the rack body 91 and extended in the vertical direction (i.e., the Z axial direction). Moreover, the rack busbar 3 is disposed adjacent to the plurality of accommodation seats 90, and the rack busbar 3 comprises a main body 31 and two branch elements 32, 33. The main body 31 is extended in the vertical direction (i.e., the Z axial direction) and forms a first plug-in interface. The two branch elements 32, 33 are symmetrical to each other and disposed on two opposite sides of the main body 31, so as to respectively form a second plug-in interface and a third plug-in interface. In the embodiment, the at least one power shelf 2 comprises a housing 20, a first input busbar 21, a second input busbar 22 and a plurality of connectors 23, 24, 25. The housing 20 comprises a rack connection edge 201, an accommodation space 202 and an installation space 204. The first input busbar 21 and the second input busbar 22 are disposed in the accommodation space 202. The plurality of connectors 23, 24, 25 are disposed at the rack connection edge 201 of the housing 20 and spaced apart along a direction (i.e., the Y axial direction in the drawing) parallel to the rack connection edge 201. In the embodiment, each of the plurality of connectors 23, 24, 25 comprises two connection terminals, which are connected to the first input busbar 21 and/or the second input busbar 22. In other embodiments, each of the plurality of connectors 23, 24, 25 comprises one or more connection terminals depending on the polarity and/or the potential configuration of the first input busbar 21 and/or the second input busbar 22. In the embodiment, the plurality of connectors comprise a first connector 23 and two second connectors 24, 25. The two second connectors 24, 25 are respectively arranged on two opposite sides of the first connector 23. Preferably but not exclusively, in other embodiments, the plurality of connectors comprise a first connector 23 and one or more second connectors, and the one or more second connectors are disposed on the same side or different sides of the first connector 23. In the embodiment, the first connector 23 is configured to connect to the first plug-in interface (i.e., the main body 31) of the rack busbar 3 along a docking direction (i.e., the X axial direction in the drawing). The two second connectors 24, 25, located to the left and right of the first connector 23, are configured to connect to the second plug-in interface and the third plug-in interface (i.e., the two branch elements 32, 33) of the rack busbar 3 along the docking direction (i.e., the X axial direction). In the embodiment, the vertical direction of the rack busbar 3 is perpendicular to the docking direction of each connector 23, 24, 25, and the vertical direction and the docking direction are perpendicular to each other. The installation space 204 of the power shelf 2 is used to receive one or more power supply units PSU. For example, in FIG. 3, there are six power supply units PSU mounted in the installation space 204. In other embodiments, the installation space 204 accommodates one or more power supply units, and one or more super capacitor units, backup battery units, other power supply units and/or other load units. In the embodiment, the power output terminals of the power supply units PSU are connected to the first input busbar 21 and the second input busbar 22, so as to supply the power to the rack busbar 3 through the first input busbar 21, the second input busbar 22 and the connectors 23, 24, 25. Preferably but not exclusively, the first input busbar 21 and the second input busbar 22 are configured to connect to different polarities or potentials. For example, the first input busbar 21 and the second input busbar 22 are configured to connect to suitable combinations of polarities or potentials, such as (positive potential, negative potential), (positive potential, ground potential), (ground potential, positive potential), (ground potential, negative potential), (negative potential, positive potential), and (negative potential, ground potential).

In the embodiment, the first connector 23, the second connector 24, 25 have the same or similar structures, but the two connection terminals of each connector can be made to have the same or different wiring changes. In the embodiment, the two connection terminals of the first connector 23 are respectively connected to the first input busbar 21 and the second input busbar 22. The two connection terminals of the second connector 24 on the left side are respectively connected to the first input busbar 21, and the two connection terminals of the second connector 25 on the right side are respectively connected to the second input busbar 22. In this way, the left side of the first connector 23 is divided into a first output terminal region, the right side of the first connector 23 is divided into a second output terminal region, and the two second connectors 24, 25 have different polarities.

In the embodiment, the main body 31 of the rack busbar 3 comprises a first output busbar 311, an insulation element 313 and a second output busbar 312, which are extended along the vertical direction (i.e., the Z axial direction). In the embodiment, the insulation element 313 is located between the first output busbar 311 and the second output busbar 312, and the first output busbar 311, the insulation element 313 and the second output busbar 312 collaboratively form the first plug-in interface. Furthermore, each of the two branch elements 32, 33 are respectively connected to one of the first output busbar 311 and the second output busbar 312. In the embodiment, the branch elements 32, 33 have similar structures and are arranged symmetrically to each other. The left branch element 32 is fixed to the outer wall of the first output busbar 311 by a fastening element 34, and the right branch element 33 is fixed to the outer wall of the second output busbar 312 by a fastening element 34. In other words, when the main body 31 is composed of the first output busbar 311 and the second output busbar 312 to form the first plug-in interface, the branch elements 32, 33 on both sides are respectively fixed to the first output busbar 311 and the second output busbar 312 by the fastening elements 34, and the second plug-in interface and the third plug-in interface with different polarities are formed. Accordingly, since the three sets of output terminals (i.e., the first connector 23 and the second connectors 24, 25) of the power shelf 2 are respectively connected to the rack busbar 3 with the branch elements, the current withstand value is increased by three times, so as to enable the higher wattage applications. Preferably but not exclusively, the first output busbar 311 and the second output busbar 312 are configured to connect to different polarities or potentials. For example, the first output busbar 311 and the second output busbar 312 are configured to connect to suitable combinations of polarities or potentials, such as (positive potential, negative potential), (positive potential, ground potential), (ground potential, positive potential), (ground potential, negative potential), (negative potential, positive potential), and (negative potential, ground potential).

In the embodiment, the rack busbar 3 further comprises a case 35 spatially corresponding to the main body 31 and branch elements 32, 33. Preferably but not exclusively, the case 35 at least partially encloses the main body 31 and the two branch elements 32, 33. The case 35 respectively permits the first plug-in interface formed by the main body 31 to be engaged with the first connector 23, and the second plug-in interface and the third plug-in interface formed by the two branch elements 32, 33 to be engaged with the two second connectors 24, 25, along the docking direction (i.e., the X axial direction). The case 35 further provides the structural support and protection for the rack busbar 3. Certainly, the present disclosure is not limited thereto. In other embodiments, the rack busbar 3 is located at the rear edge of the rack body 91, the main body 31 provides sufficient structural support, and the case 35 is omitted. Alternatively, in another embodiment, the structural support and protection is provided by the rear cover of the rack body 91.

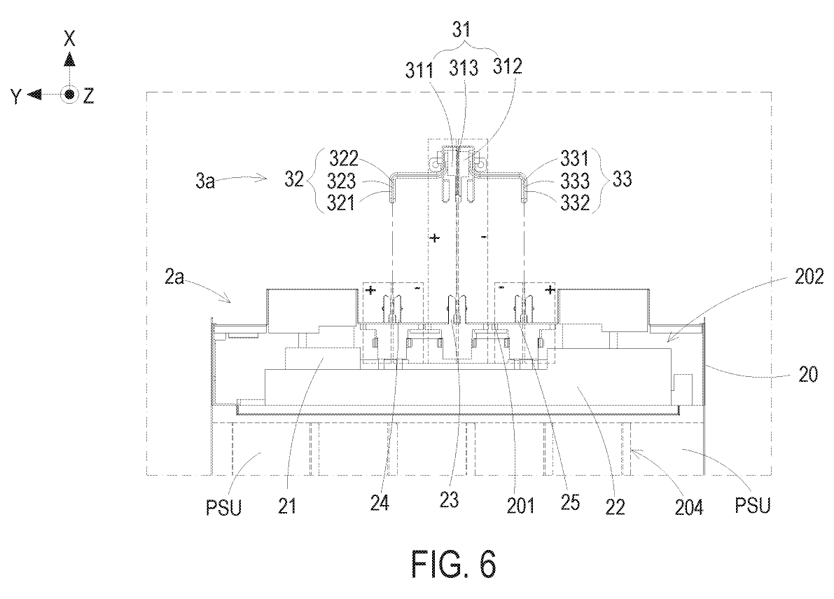

FIG. 6 is a top view illustrating partial components of a power shelf and a rack busbar according to a second embodiment of the present disclosure. In the embodiment, the structures, elements and functions of the power shelf 2a and the rack busbar 3a are similar to those of the power shelf 2 and the rack busbar 3 of FIGS. 1 - 5, and are not redundantly described herein. In the embodiment, the two connection terminals of the first connector 21 of the power shelf 2a are respectively connected to the first input busbar 21 and the second input busbar 22, and the two connection terminals of each second connector 24, 25 are respectively connected to the first input busbar 21 and the second input busbar 22. In that, the first connector 23 and the two second connectors 24, 25 form three identical sets of output terminals.

In the embodiment, the main body 31 of the rack busbar 3a comprises a first output busbar 311, an insulation element 313 and a second output busbar 312, which are extended along the vertical direction (i.e., the Z axial direction). In the embodiment, the insulation element 313 is located between the first output busbar 311 and the second output busbar 312, and the first output busbar 311, the insulation element 313 and the second output busbar 312 collaboratively form the first plug-in interface. In the embodiment, the branch element 32 comprises a first conductor 321, a spacer 323 and a second conductor 322, the spacer 323 is located between the first conductor 321 and the second conductor 322, and the first conductor 321 and the second conductor 322 are respectively connected to the first output busbar 311 and the second output busbar 312. The second plug-in interface formed by the branch element 32 is similar to the first plug-in interface. Similarly, the branch element 33 comprises a first conductor 331, a spacer 333 and a second conductor 332, the spacer 333 is located between the first conductor 331 and the second conductor 332, and the first conductor 331 and the second conductor 332 are respectively connected to the first output busbar 311 and the second output busbar 312. The third plug-in interface formed by the branch element 33 is similar to the first plug-in interface. In other words, the two branch elements 32, 33 are respectively arranged on both sides of the main body 31, and form the second plug-in interface and the third plug-in interface with the same structure of the main body 31.

In this way, as the three identical sets of output terminals (i.e., the first connector 23 and the second connectors 24, 25) of the power shelf 2a are respectively connected to the rack busbar 3a with the branch elements, the current withstand value of the aforementioned power supply system 1 is increased by three times, and the higher wattage applications are achieved. Certainly, the present disclosure is not limited thereto.

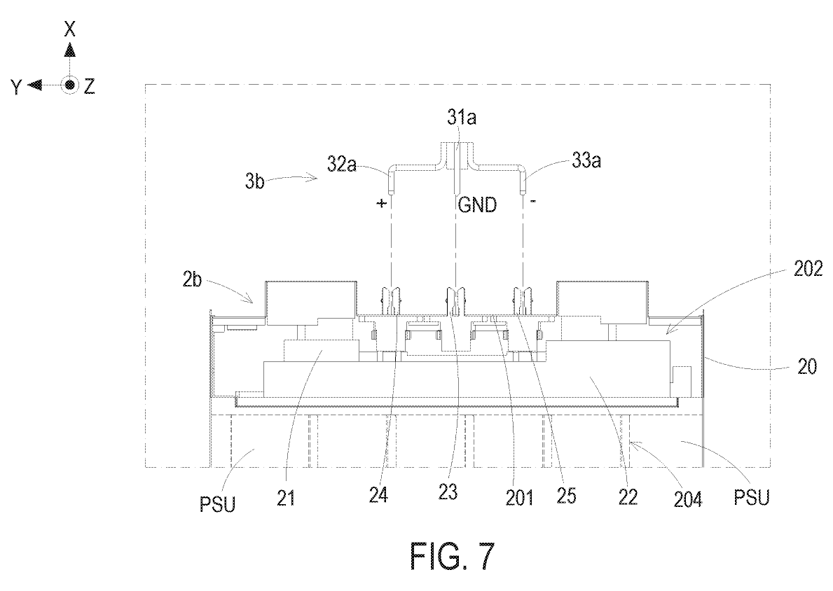

FIG. 7 is a top view illustrating partial components of a power shelf and a rack busbar according to a third embodiment of the present disclosure. In the embodiment, the structures, elements and functions of the power shelf 2b and the rack busbar 3b are similar to those of the power shelf 2 and the rack busbar 3 of FIGS. 1 - 5, and are not redundantly described herein. In the embodiment, the two connection terminals of the first connector 23 on the power shelf 2b are grounded. Namely, the first connector 23 is configured as a ground connector. The two connection terminals of the second connector 24 are connected to the first input busbar 21. Namely, the second connector 24 is configured as a first polarity connector. The two connection terminals of the other second connector 25 are connected to the second input busbar 22. Namely, the other second connector 25 is configured as a second polarity connector. For example, the first connector 23, the second connector 24, and the other second connector 25 respectively provide ground potential, 400V and -400V voltage outputs.

On the other hand, the main body 31a of the rack busbar 3b can be formed by a copper busbar to form a ground busbar GND. Moreover, the two branch elements 32a, 33a are spaced apart from the main body 31a with the insulation element, and respectively form a first polarity output busbar and a second polarity output busbar with copper busbar structure.

In this way, as the main body 31a and the two branch elements 32a, 33a of the rack busbar 3b are connected to the first connector 23 and the two second connectors 24, 25 of the power shelf 2b, the current withstand value of the aforementioned power supply system 1 can be increased to achieve the higher wattage application.

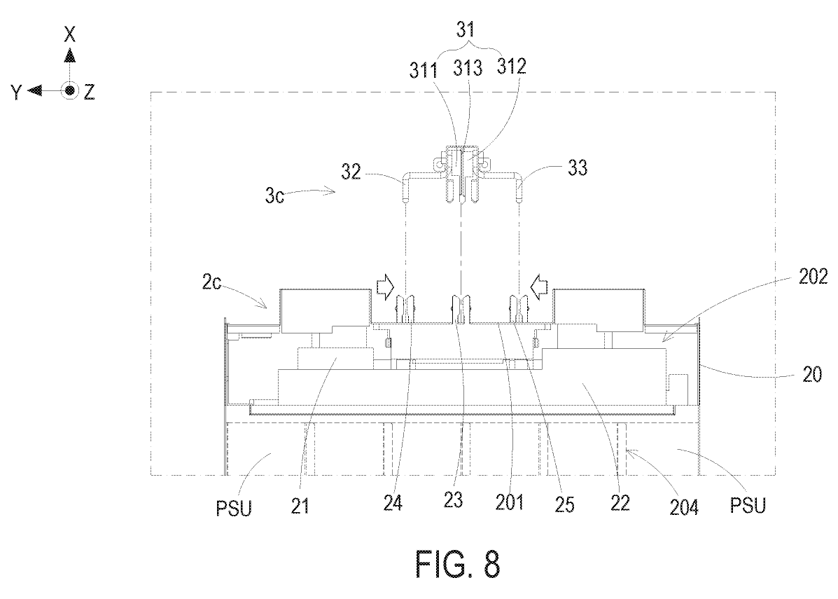

FIG. 8 is a top view illustrating partial components of a power shelf and a rack busbar according to a fourth embodiment of the present disclosure. In the embodiment, the structures, elements and functions of the power shelf 2c and the rack busbar 3c are similar to those of the power shelf 2 and the rack busbar 3 of FIGS. 1 - 5, and are not redundantly described herein. In the embodiment, the first connector 23 and the two second connectors 24, 25 are further integrally formed as a single structure along the direction (i.e., the Y axial direction) parallel to the rack connection edge 201 is extended. With the wiring at the connection points of the first connector 23 and the second connectors 24, 25 unaffected, the single structure ensures that the power shelf 2c can be stably and reliably plugged into the rack busbar 3c. Similarly, the spacing of the branch elements 32, 33 can be further adjusted on the corresponding rack busbar 3c.

From the above, the power supply system 1 of the present disclosure utilizes the wiring diversification of multiple connectors 23, 24, 25 of the power shelves 2, 2a, 2b, 2c, and in conjunction with the setting of multiple plug-in interfaces of the rack busbars 3, 3a, 3b, 3c, to pair with each other, so that the power supply system 1 can break through the limitation of using one single connector and provide higher wattage or more diversified application scenarios. Certainly, the number and connection end combination of the first connector 23, the second connectors 24, 25, and the number and type of the branch elements 32, 33, 32a, 33a are adjustable according to the practical requirements, and the present disclosure is not limited thereto. For example, in the above embodiments, the positive and negative terminals of the first input busbar 21 and the second input busbar 22 are only for illustrative purposes. Preferably but not exclusively, in the drawing, the first input busbar 21 is configured to connect to a negative voltage and the second input busbar 22 is configured to connect to a positive voltage, or the first input busbar 21 is configured to connect to a positive voltage and the second input busbar 22 is configured to connect to the ground potential, and so on, for various suitable power supply connection methods.

In the above embodiments, the terms "input" and "output" for the input busbar of the power shelf and the output busbar of the rack busbar are used for simplifying the explanation only and do not mean that power can only be transmitted from the power shelf to the rack busbar. In other implementations, depending on the characteristics of the power supply units and/or load units installed in the power shelf, the input busbar of the power shelf and the output busbar of the rack busbar can respectively play the roles of power input and/or power output. For example, as the power shelf is equipped with a BBU unit, the power shelf can transfer the power of the battery from the input busbar to the output busbar at time A, and receive the power from the output busbar to charge the battery through the input busbar at time B.

In summary, the present disclosure provides a power supply system and a power shelf and a rack thereof. By arranging plural sets of output terminals between the power shelf and the rack, it allows the power supply system to break through the maximum current carrying capacity in application. A plurality of connectors are arranged on the power shelf to form, for example, at least three sets of output terminals, and two branch elements are added on two opposite sides of the main body of the rack busbar, so that it allows the power supply system to break through the maximum current carrying capacity in application. As the main body of the rack busbar is composed of the first output busbar and the second output busbar to form the first plug-in interface, the branch elements on both sides are fixed to the first output busbar and the second output busbar respectively by fastening elements, and two plug-in interfaces with different polarities are formed. In that, as the three sets of output terminals of the power shelf are respectively connected to the rack busbar with the branch elements, the current withstand value is increased by three times, so as to enable the higher wattage applications. Certainly, the branch element can also be composed of, for example, a spacer, a first conductor and a second conductor. The first conductor and the second conductor are insulated by the spacer, and respectively connected to the first output busbar and the second output busbar, and two plug-in interfaces the same as the main body are formed. In this way, as the three sets of output terminals of the power shelf are respectively connected to three sets of plug-in interfaces, the current withstand value of the power supply system is increased by three times, and the higher wattage applications are achieved. In addition, the main body of the rack busbar and the branch elements on both sides can also be directly constructed as a ground busbar, a first output busbar and a second output busbar, which can be connected to the three connectors of the power shelf, so as to realize the diversified applications of the power supply system. On the other hand, the rack busbar can be easily equipped with a case to provide the structural support and protection. The plurality of connectors of the power shelf can also be integrally formed as a single structure. It facilitates the miniaturization of the entire structure and improves the power density of the power system.

While the disclosure has been described in terms of what is presently considered to be the most practical and preferred embodiments, it is to be understood that the disclosure needs not be limited to the disclosed embodiment. On the contrary, it is intended to cover various modifications and similar arrangements comprised within the spirit and scope of the appended claims which are to be accorded with the broadest interpretation so as to encompass all such modifications and similar structures.

What is claimed is:

1. A power supply system, comprising:
a rack, comprising:
a rack body, comprising a plurality of accommodation seats stacked in a vertical direction; and
a rack busbar, arranged in the vertical direction and disposed adjacent to the plurality of accommodation seats, wherein the rack busbar comprises:
a main body, extended in the vertical direction and forming a first plug-in interface; and
two branch elements, disposed on two opposite sides of the main body, and respectively forming a second plug-in interface and a third plug-in interface; and
at least one power shelf, detachably received in one of the plurality of accommodation seats, wherein the at least one power shelf comprises:
a housing, comprising a rack connection edge, an accommodation space and an installation space for receiving one or more power supply units and/or load units;
a first input busbar and a second input busbar, disposed in the accommodation space for connecting to the one or more power supply units and/or load units; and
a plurality of connectors, disposed at the rack connection edge of the housing and spaced apart along a direction parallel to the rack connection edge, wherein each of the plurality of connectors comprises two connection terminals, which are connected to the first input busbar and/or the second input busbar, wherein the plurality of connectors comprise a first connector and two second connectors, the two second connectors are respectively arranged on two opposite sides of the first connector, the first connector is configured to connect to the first plug-in interface of the rack busbar along a docking direction, the two second connectors are configured to connect to the second plug-in interface and the third plug-in interface of the rack busbar along the docking direction, and the vertical direction and the docking direction are perpendicular to each other.

2. The power supply system according to claim 1, wherein the two connection terminals of the first connector are respectively connected to the first input busbar and the second input busbar, the two second connectors are respectively connected to the first input busbar and the second input busbar, and the two second connectors have different polarities.

3. The power supply system according to claim 1, wherein the two connection terminals of the first connector are respectively connected to the first input busbar and the second input busbar, and the two connection terminals of the second connector are respectively connected to the first input busbar and the second input busbar.

4. The power supply system according to claim 1, wherein the first connector is a ground connector, and the two second connectors are respectively a first polarity connector and a second polarity connector.

5. The power supply system according to claim 1, wherein the plurality of connectors are integrally formed as a single structure along the direction parallel to the rack connection edge.

6. The power supply system according to claim 1, wherein the main body comprises a first output busbar, an insulation element and a second output busbar extended along the vertical direction, wherein the insulation element is located between the first output busbar and the second output busbar, and the first output busbar, the insulation element and the second output busbar collaboratively form the first plug-in interface, wherein each of the two branch elements is respectively connected to one of the first output busbar and the second output busbar.

7. The power supply system according to claim 1, wherein the main body comprises a first output busbar, an insulation element and a second output busbar extended along the vertical direction, the insulation element is located between the first output busbar and the second output busbar, and the first output busbar, the insulation element and the second output busbar collaboratively form the first plug-in interface, wherein each of the two branch elements comprises a first conductor, a spacer and a second conductor, the spacer is located between the first conductor and the second conductor, and the first conductor and the second conductor are respectively connected to the first output busbar and the second output busbar.

8. The power supply system according to claim 1, wherein the main body comprises a ground busbar, and the two branch elements respectively comprise a first polarity output busbar and a second polarity output busbar.

9. The power supply system according to claim 1, wherein the rack busbar further comprises a case, at least partially enclosing the main body and the two branch elements, wherein the case permits the first plug-in interface, the second plug-in interface and the third plug-in interface to be engaged with the first connector and the two second connectors along the docking direction.

10. A power shelf, comprising:
a housing, comprising a rack connection edge, an accommodation space and an installation space for receiving one or more power supply units and/or load units;
a first input busbar and a second input busbar disposed within the accommodation space for connecting the one or more power supply units and/or load units; and
a plurality of connectors, disposed at the rack connection edge of the housing and spaced apart along a direction parallel to the rack connection edge, wherein each of the plurality of connectors comprises two connection terminals, which are respectively connected to the first input busbar and/or the second input busbar, wherein the plurality of connectors comprise a first connector and two second connectors, the two second connectors are respectively arranged on two opposite sides of the first connector, the first connector is configured to connect to a main body of a rack busbar along a docking direction, and the two second connectors are configured to connect to two branch elements of the rack busbar along the docking direction, wherein the main body is extended in a vertical direction, the two branch elements are respectively arranged on two opposite sides of the main body, and the vertical direction and the docking direction are perpendicular to each other.

11. The power shelf according to claim 10, wherein the two connection terminals of the first connector are respectively connected to the first input busbar and the second input busbar, the two connection terminals of the two second connectors are respectively connected to the first input busbar or the second input busbar, and the two second connectors have different polarities.

12. The power shelf according to claim 10, wherein the two connection terminals of the first connector are respectively connected to the first input busbar and the second input busbar, and the two connection terminals of the second connector are respectively connected to the first input busbar and the second input busbar.

13. The power shelf according to claim 10, wherein the first connector is a ground connector, and the two second connectors are respectively a first polarity connector and a second polarity connector.

14. The power shelf according to claim 10, wherein the plurality of connectors are integrally formed as a single structure along the direction parallel to the rack connection edge.

15. A rack, comprising:
a rack body, comprising a plurality of accommodation seats stacked in a vertical direction; and
a rack busbar, arranged in the vertical direction and disposed adjacent to the plurality of accommodation seats, wherein the rack busbar comprises:
a main body, extended in the vertical direction and forming a first plug-in interface, wherein the first plug-in interface is configured to connect to a first connector of a power shelf along a docking direction, and the vertical direction is perpendicular to the docking direction; and
two branch elements, disposed on two opposite sides of the main body, and respectively forming a second plug-in interface and a third plug-in interface, wherein the second plug-in interface and the third plug-in interface are configured to connect to two second connectors of the power shelf along the docking direction, and the two second connectors are disposed on two opposite sides of the first connector.

16. The rack according to claim 15, wherein the main body comprises a first output busbar, an insulation element and a second output busbar extended along the vertical direction, wherein the insulation element is located between the first output busbar and the second output busbar, and the first output busbar, the insulation element and the second output busbar collaboratively form the first plug-in interface, wherein the two branch elements are respectively connected to the first output busbar and the second output busbar.

17. The rack according to claim 15, wherein the main body comprises a first output busbar, an insulation element and a second output busbar extended along the vertical direction, the insulation element is located between the first output busbar and the second output busbar, and the first output busbar, the insulation element and the second output busbar collaboratively form the first plug-in interface, wherein each of the two branch elements comprises a first conductor, a spacer and a second conductor, the spacer is located between the first conductor and the second conductor, and the first conductor and the second conductor are respectively connected to the first output busbar and the second output busbar.

18. The rack according to claim 15, wherein the main body is a ground busbar, and the two branch elements are respectively a first polarity output busbar and a second polarity output busbar.

19. The rack according to claim 15, further comprising a case at least partially enclosing the main body and the two the branch elements, wherein the case permits the first plug-in interface, the second plug-in interface and the third plug-in interface to be engaged with the first connector and the two second connectors along the docking direction.
